(19) United States
(12) Patent Application Publication
(10) Pub. No.: US 2010/0206356 A1
(43) Pub. Date: Aug. 19, 2010

(54) Rotational Trough Reflector Array For Solar-Electricity Generation

(75) Inventors: Patrick C. Cheung, Castro Valley, CA (US); Patrick Y. Maeda, Mountain View, CA (US)

Correspondence Address: BEVER, HOFFMAN & HARMS, LLP, 901 CAMPISI WAY, SUITE 370, CAMPBELL, CA, 95008, US

(73) Assignee: Palo Alto Research Center Incorporated, Palo Alto, CA (US)

(21) Appl. No.: 12/388,500

(22) Filed: Feb. 18, 2009

(51) Int. Cl. H01L 31/052

(52) U.S. Cl. 136/246

(57) ABSTRACT

A rotational trough reflector solar-electricity generation device includes a trough reflector that rotates around a substantially vertical axis. A strip-type photovoltaic (PV) device is fixedly mounted along the focal line of the trough reflector. A tracking system rotates the trough reflector such that the trough reflector is aligned generally parallel to the incident sunlight (e.g., in a generally east-west direction at sunrise, turning to generally north-south at noon, and turning generally west-east at sunset). A disc-shaped support structure is used to distribute the reflector's weight over a larger area and to minimize the tracking system motor size. Multiple trough reflectors are mounted on the disc-shaped support to maximize power generation.

### FIELD OF THE INVENTION

The present invention relates generally to an improvement in solar-electricity generation, and more particularly to an improved trough reflector-type solar-electricity generation device that is suitable for either residential rooftop-mounted applications or commercial applications.

### BACKGROUND OF THE INVENTION

The need for “green” sources of electricity (i.e., electricity not produced by petroleum-based products) has given rise to many advances in solar-electricity generation for both commercial and residential applications.

Solar-electricity generation typically involves the use of photovoltaic (PV) elements (solar cells) that convert sunlight directly into electricity. These solar cells are typically made using square or quasi-square silicon wafers that are doped using established semiconductor fabrication techniques and absorb light irradiation (e.g., sunlight) in a way that creates free electrons, which in turn are caused to flow in the presence of a built-in field to create direct current (DC) power. The DC power generated by an array including several solar cells is collected on a grid placed on the cells.

Solar-electricity generation is currently performed in both residential and commercial settings. In a typical residential application, a relatively small array of solar cells is mounted on a house's rooftop, and the generated electricity is typically supplied only to that house. In commercial applications, larger arrays are disposed in sunlit, otherwise unused regions (e.g., deserts), and the resulting large amounts of power are conveyed by power lines to businesses and houses over power lines. The benefit of mounting solar arrays on residential houses is that the localized generation of power reduces losses associated with transmission over long power lines, and requires fewer resources (i.e., land, power lines and towers, transformers, etc.) to distribute the generated electricity in comparison to commercially-generated solar-electricity. However, as set forth below, current solar-electricity generation devices are typically not economically feasible in residential settings.

Solar-electricity generation devices can generally be divided in to two groups: flat panel solar arrays and concentrating-type solar devices. Flat panel solar arrays include solar cells that are arranged on large, flat panels and subjected to unfocused direct and diffuse sunlight, whereby the amount of sunlight converted to electricity is directly proportional to the area of the solar cells. In contrast, concentrating-type solar devices utilize an optical element that focuses (concentrates) mostly direct sunlight onto a relatively small solar cell located at the focal point (or line) of the optical element.

Flat panel solar arrays have both advantages and disadvantages over concentrating-type solar devices. An advantage of flat panel solar arrays is that their weight-to-size ratio is relatively low, facilitating their use in residential applications because they can be mounted on the rooftops of most houses without significant modification to the roof support structure. However, flat panel solar arrays have relatively low efficiencies (i.e., approximately 15%), which requires large areas to be covered in order to provide sufficient amounts of electricity to make their use worthwhile. Thus, due to the high cost of silicon, current rooftop flat panel solar arrays cost over $5 per Watt, so it can take 25 years for a home owner to recoup the investment by the savings on his/her electricity bill. Economically, flat panel solar arrays are not a viable investment for a typical homeowner without subsidies.

By providing an optical element that focuses (concentrates) sunlight onto a solar cell, concentrating-type solar arrays avoid the high silicon costs of flat panel solar arrays, and may also exhibit higher efficiency through the use of smaller, higher efficiency solar cells. The amount of concentration varies depending on the type of optical device, and ranges from 10× to 100× for trough reflector type devices (described in additional detail below) to as high as 600× to 10,000× using some cassegrain-type solar devices. However, a problem with concentrating-type solar devices in general is that the orientation of the optical element must be continuously adjusted using a tracking system throughout the day in order to maintain peak efficiency, which requires a substantial foundation and motor to support and position the optical element, and this structure must also be engineered to withstand wind and storm forces. Moreover, higher efficiency (e.g., cassegrain-type) solar devices require even higher engineering demands on reflector material, reflector geometry, and tracking accuracy. Due to the engineering constraints imposed by the support/tracking system, concentrating-type solar devices are rarely used in residential settings because the rooftop of most houses would require substantial retrofitting to support their substantial weight. Instead, concentrating-type solar devices are typically limited to commercial settings in which cement or metal foundations are disposed on the ground.

FIGS. 10(A) to 10(C) are simplified perspective views showing a conventional trough reflector solar-electricity generation device 50, which represents one type of conventional concentrating-type solar device. Device 50 generally includes a trough reflector 51, having a mirrored (reflective) surface 52 shaped to reflect solar (light) beams B onto a focal line FL, an elongated photoreceptor 53 mounted in fixed relation to trough reflector 51 along focal line FL by way of support arms 55, and a tracking system (not shown) for supporting and rotating trough reflector 51 around a horizontal axis X that is parallel to focal line FL. In conventional settings, trough reflector 51 is positioned with axis X aligned in a north-south direction, and as indicated in FIGS. 10(A) to 10(C), the tracking system rotates trough reflector 51 in an east-to-west direction during the course of the day such that beams B are directed onto mirror surface 52. As mentioned above, a problem with this arrangement in a residential setting is that the tracking system (i.e., the support structure and motor needed to rotate trough reflector 51) requires significant modifications to an average residential house rooftop. On the other hand, if the troughs are made small and are packed together side by side, and multiple troughs driven from one motor, then there is an engineering difficulty to keep the multiple hinges and linkages to pivot together to precisely focus sunlight.

What is needed is an economically viable residential rooftop-mounted solar-electricity generation system that overcomes the problems associated with conventional solar-electricity generation systems set forth above. In particular, what is needed is a solar-electricity generation device that utilizes less PV material than conventional flat panel solar arrays, and avoids the heavy, expensive tracking systems of conventional concentrating-type solar devices.

### SUMMARY OF THE INVENTION

The present invention is directed to solar-electricity generation device (apparatus) in which a trough reflector is rotated by a tracking system around an axis that is substantially orthogonal (e.g., generally vertical) to an underlying support surface, and non-parallel (e.g., perpendicular) to the focal line defined by the trough reflector (i.e., not horizontal as in conventional trough reflector systems), and in which the tracking system aligns the trough reflector generally parallel to incident solar beams (e.g., aligned in a generally east-west direction at sunrise, not north/south as in conventional trough reflector systems). By using the moderate solar concentration provided by the trough reflector, the amount of PV material required by the solar-electricity generation device is reduced roughly ten to one hundred times over conventional solar panel arrays. In addition, by rotating the trough reflector around an axis that is perpendicular to the focal line, the trough reflector remains in-plane with or in a fixed, canted position relative to an underlying support surface (e.g., the rooftop of a residential house), thereby greatly reducing the engineering demands on the strength of the support structure and the amount of power required to operate the tracking system, avoiding the problems associated with adapting commercial trough reflector devices, and providing an economically viable solar-electricity generation device that facilitates residential rooftop implementation.

According to a specific embodiment of the present invention, multiple trough reflectors are mounted onto a disc-shaped support structure that is rotated by a motor mounted on the peripheral edge of the support structure. The weight of the trough reflectors is spread by the disc-shaped support structure over a large area, thereby facilitating rooftop mounting in residential applications. A relatively small motor coupled to the peripheral edge of the disc-shaped support substrate turns the support structure using very little power in comparison to that needed in conventional trough reflector arrangements. PV elements mounted onto each trough reflector are connected in series using known techniques to provide maximum power generation. The low profile of the disc-shaped support and the in-plane rotation of the trough reflectors reduces the chance of wind and storm damage in comparison to conventional trough reflector arrangements.

According to another specific embodiment of the present invention, multiple trough reflectors are mounted onto a disc-shaped support structure that is supported in a raised, angled position by a vertical support shaft that is turned by a motor such that the trough reflectors are directed to face the sun. Although raising and tilting the plane defined by the trough reflector support potentially increases wind effects over the perpendicular arrangement, the raised arrangement may provide better solar light conversion that may be useful in some commercial applications.

### BRIEF DESCRIPTION OF THE DRAWINGS

These and other features, aspects and advantages of the present invention will become better understood with regard to the following description, appended claims, and accompanying drawings, where:

FIG. 1 is a top side perspective view showing a solar-electricity generation apparatus according to a generalized embodiment of the present invention;

FIGS. 2(A) and 2(B) are simplified cross-sectional end and side views showing a trough reflector of the apparatus of FIG. 1 during operation;

FIG. 3 is a perspective top view showing the apparatus of FIG. 1 disposed on the rooftop of a residential house;

FIGS. 4(A), and 4(B) and 4(C) are simplified perspective views showing a method for positioning the trough reflector of FIG. 1 during operation according to an embodiment of the present invention;

FIG. 5 is a top side perspective view showing a solar-electricity generation apparatus according to another embodiment of the present invention;

FIGS. 6(A), and 6(B) and 6(C) are simplified top views showing the apparatus of FIG. 5 during operation;

FIG. 7 is a top side perspective view showing a solar-electricity generation apparatus according to another embodiment of the present invention;

FIGS. 8(A), and 8(B) and 8(C) are simplified top views showing the apparatus of FIG. 7 during operation;

FIGS. 9(A), and 9(B) and 9(C) are simplified perspective views showing a solar-electricity generation apparatus according to another embodiment of the present invention; and

FIGS. 10(A), and 10(B) and 10(C) are simplified perspective views showing a conventional trough reflector solar-electricity generation device during operation.

### DETAILED DESCRIPTION OF THE DRAWINGS

The present invention relates to an improvement in solar-electricity generation devices. The following description is presented to enable one of ordinary skill in the art to make and use the invention as provided in the context of a particular application and its requirements. As used herein, directional terms such as “vertical” and “horizontal” are intended to provide relative positions for purposes of description, and are not intended to designate an absolute frame of reference. Various modifications to the preferred embodiment will be apparent to those with skill in the art, and the general principles defined herein may be applied to other embodiments. Therefore, the present invention is not intended to be limited to the particular embodiments shown and described, but is to be accorded the widest scope consistent with the principles and novel features herein disclosed.

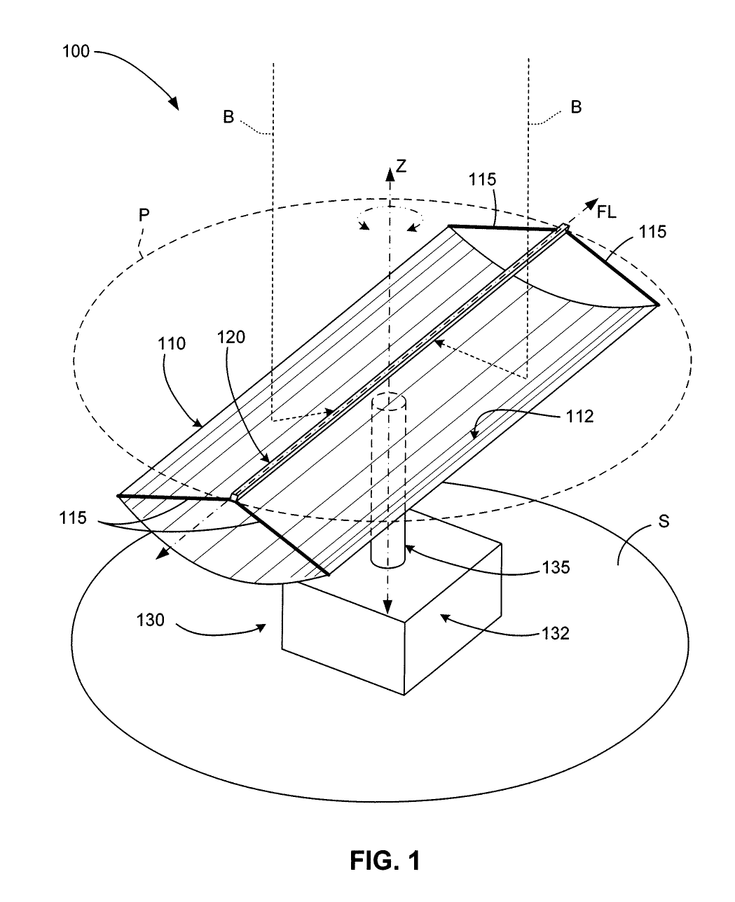

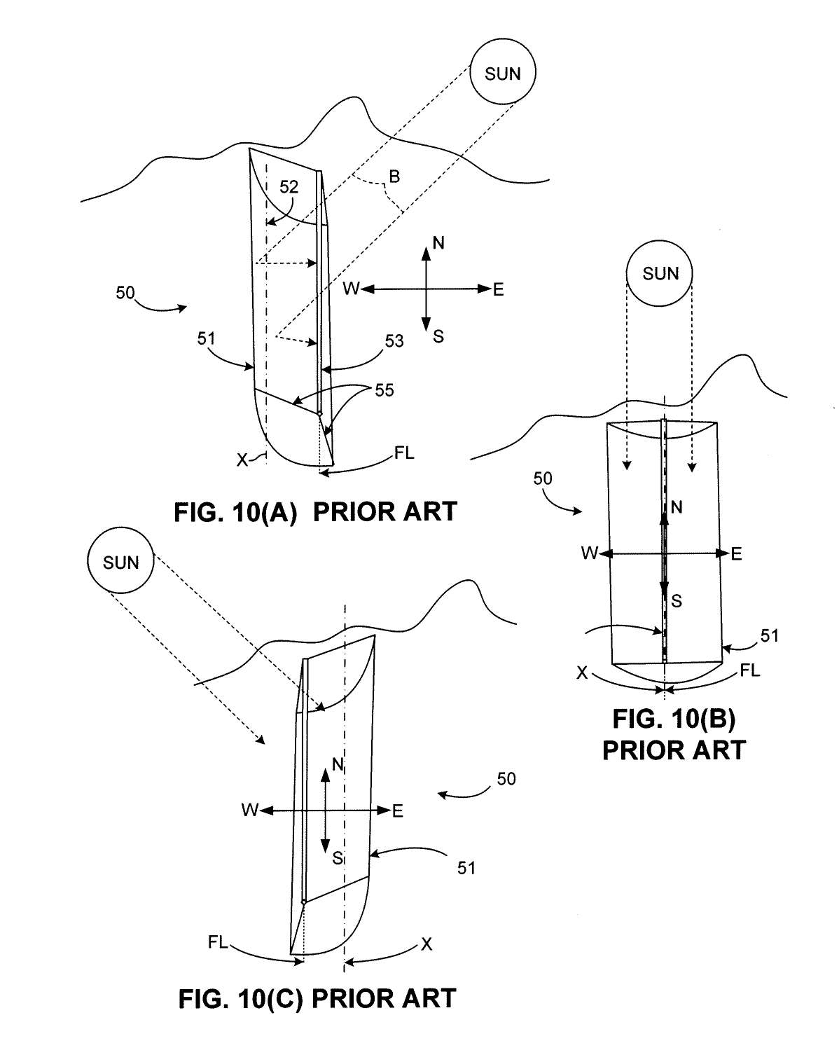

FIG. 1 is a simplified perspective view showing a solar-electricity generation device (apparatus) 100 according to a simplified embodiment of the present invention. Device 100 generally includes a trough reflector 110, having a mirrored (reflective) surface 112 shaped to reflect solar (light) beams B onto a focal line FL, a photoreceptor 120 mounted in fixed relation to trough reflector 110 along focal line FL, and a tracking system 130 for rotating (or pivoting) trough reflector 110 around an axis Z that is non-parallel focal line FL. That is, as set forth below, trough reflector 110 is configured in substantially the same manner as in conventional systems, but device 100 differs from conventional systems in that instead of being rotated around an axis that is horizontal to the trough reflector's focal line and underlying support surface (e.g., axis X in FIGS. 10(A) to 10(C), discussed above), device 100 rotates trough reflector 110 around axis Z, which is substantially perpendicular to focal line FL and underlying support surface S. As set forth below, this arrangement greatly facilitates utilizing device 100 in residential settings, but also provides an improved apparatus for commercial solar-electricity generation as well.

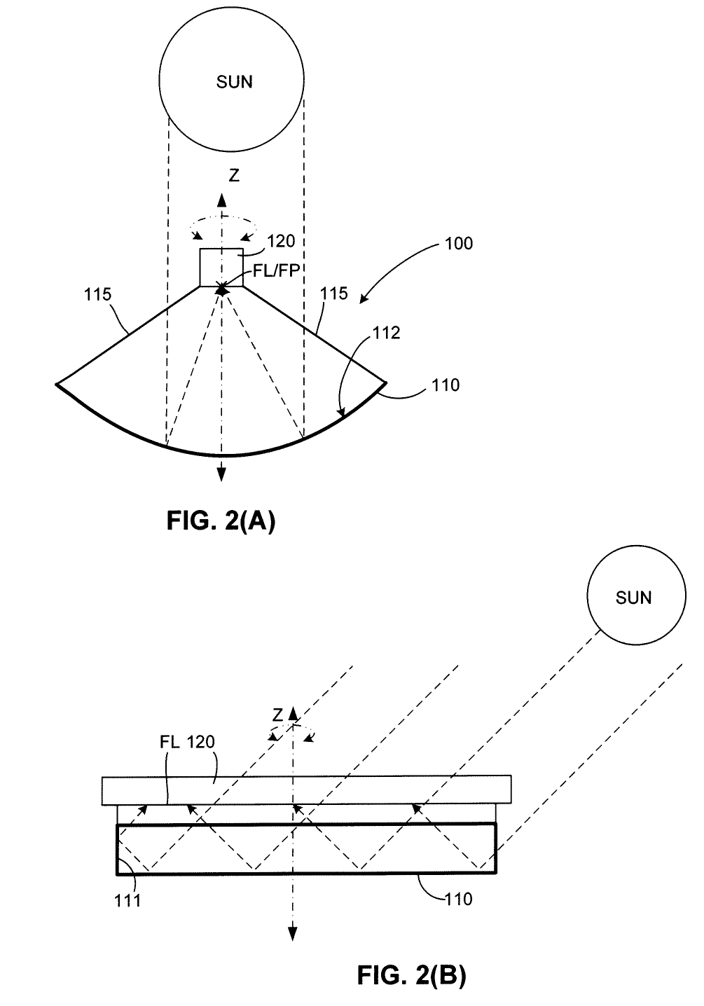

Referring to the center of FIG. 1, trough reflector 110 comprises a light weight rigid material (e.g., aluminum, plastic, metal, etc.) that supports reflective surface 112 thereon. As indicated in FIG. 2(A), reflective surface 112 comprises a standard mirror material or coating (e.g., silver, aluminum, chrome, etc) that is disposed or otherwise forms an elongated, curved (e.g., cylindrical parabolic) surface arranged such that incident light beams directed to surface 112 are reflected from any point along a cross-sectional region of trough reflector 110 onto a focal point FP. As used herein, focal line FL describes the loci of the focal points FP generated along the entire length of reflective surface 112. In an alternative embodiment (not shown), multiple flat mirror facets may be arranged using known techniques in a generally cylindrical parabolic shape to generate the reflective surface functions described herein.

PV element 120 traverses the length of trough reflector 110, and is maintained in a fixed position relative to reflective surface 112 by way of a support structure 115. PV element 120 is an elongated structure formed by multiple pieces of semiconductor (e.g., silicon) connected end-to-end, where each piece (strip) of semiconductor is fabricated using known techniques in order to convert the incident sunlight to electricity. The multiple semiconductor pieces are coupled by way of wires or other conductors (not shown) to adjacent pieces in a series arrangement. Although not specific to the fundamental concept of the present invention, the will keep using the silicon photovoltaic material commonly used to build solar panel but will try to harness 10× or more of electricity from the same active area. Other PV materials that are made from thin film deposition can also be used; and when high efficiency elements such as those made from multi-junction processes becomes economically viable they can also be used in this configuration.

According to another aspect of the invention, PV element 120 is precisely positioned along focal line FL by way of support structure 115 using any of a number of possible approaches. In the embodiment illustrated in FIG. 1, PV element 120 is mounted on a metal bar which in turn is suspended by multiple metal arms that are cantilevered out from trough reflector 110. In an alternative embodiment (not shown), PV element 120 is attached and integrated under a transparent support member (e.g., a large piece of glass or other transparent material that shields the parts from the weather elements). In yet another alternative embodiment, in an embodiment including multiple trough reflectors, PV elements may be mounted onto the reverse (i.e., nonreflecting) surfaces of adjacent trough reflectors in a manner similar to that described, for example, in U.S. Pat. No. 5,180,441, which is incorporated herein by reference in its entirety. In yet another alternative embodiment, similar to the cassegrain architecture, sunlight can be reflected off a secondary reflective trough mounted near the focus line of the primary trough, and through a long opening at the bottom of the primary trough. The PV element can then be mounted on the bottom tray to ease thermal management.

As indicated in FIG. 1, in accordance with an embodiment of the present invention, PV element 120 is disposed such that focal line FL is parallel to underlying planar support surface S, and axis Z is perpendicular to surface S (and focal line FL), whereby PV element 120 remains in a plane P that is parallel to underlying support surface S. This arrangement greatly reduces the engineering demands on the structural strength and power required by tracking system 130 in comparison to commercial trough reflector devices, and, as described in additional detail below, provides an economically viable solar-electricity generation device that facilitates residential rooftop implementation.

In accordance with an aspect of the present invention, tracking system 130 detects the position of the sun relative to trough reflector 110, and rotates trough reflector 110 such that trough reflector 110 is generally parallel to the projection of the solar beams onto the plane of the array. According to the generalized embodiment shown in FIG. 1, tracking system 130 includes a motor 132 that is mechanically coupled to trough reflector 110 (e.g., by way of an axle 135) such that mechanical force (e.g., torque) generated by the motor 132 causes trough reflector 110 to rotate around axis Z. Tracking system 130 also includes a sensor (not shown) that detects the sun's position, and a processor or other mechanism for calculating an optimal rotational angle G of trough reflector 110 around axis Z. Due to the precise, mathematical understanding of planetary and orbital mechanics, the tracking can be determined by strictly computational means once the system is adequately located. In one embodiment, a set of sensors including GPS and photo cells are used with a feedback system to correct any variations in the drive train. In other embodiments such a feedback system may not be necessary.

The operational idea is further illustrated with reference to FIGS. 2(A) and 2(B). Referring to FIG. 2(A), when trough reflector 110 is aligned parallel to the sun ray's that are projected onto device 100, the sun's ray will be reflected off the cylindrical parabolic mirror surface 112 and onto PV element 120 as a focused line (see FIG. 2(B)). The concept is similar to the textbook explanation of how parallel beams of light can be reflected and focused on to the focal point FP of a parabolic reflector, except that the parallel beams rise from below the page in FIG. 2(A), and the reflected rays emerge out of the page onto focal line FL (which is viewed as a point in FIG. 2(A), and is shown in FIG. 2(B)).

The concentration scheme depicted in FIGS. 2(A) and 2(B) provides several advantages over conventional approaches. In comparison to convention cassegrain-type solar devices having high concentration ratios (e.g., 600× to 10,000×), the target ratio of 10× to 100× associated with the present invention reduces the engineering demands on reflector material, reflector geometry, and tracking accuracy. Conversely, in comparison to the high silicon costs of conventional flat panel solar arrays, achieving even a moderate concentration ratio (i.e., 25×) is adequate to bring the portion of cost of silicon photovoltaic material needed to produced PV element 120 to a small fraction of overall cost of device 100, which serves to greatly reduce costs over conventional flat panel solar arrays.

The side view shown in FIG. 2(B) further illustrates how sunlight directed parallel to focal line FL at a non-zero incident angle will still reflect off trough reflector 110 and will focus onto PV element 120. A similar manner of concentrating parallel beams of light can also be implemented by having the beams pass through a cylindrical lens, cylindrical Fresnel lens, or curved or bent cylindrical Fresnel lens but the location of the focal line will move toward the lens with increasing incidence angle of the sunlight due to the refractive properties of the lens and would degrade performance relative to a reflective system.

An optional flat mirror 111 may be placed at the end trough reflector 110 (see the left side of FIG. 2(B)) to reflect light back to PV element 120 to facilitate making a length of PV element 120 substantially equal to the length of trough reflector 110. In this case the PV elements near the mirror's end can be hotter than most of the other elements when the incident solar beam is far from being perpendicular. Due to the fact that Silicon PV elements when wired in series cannot utilize the current generated by a single element in the series, PV elements in the hot sections of multiple troughs can be grouped together and be wired in a separate circuit.

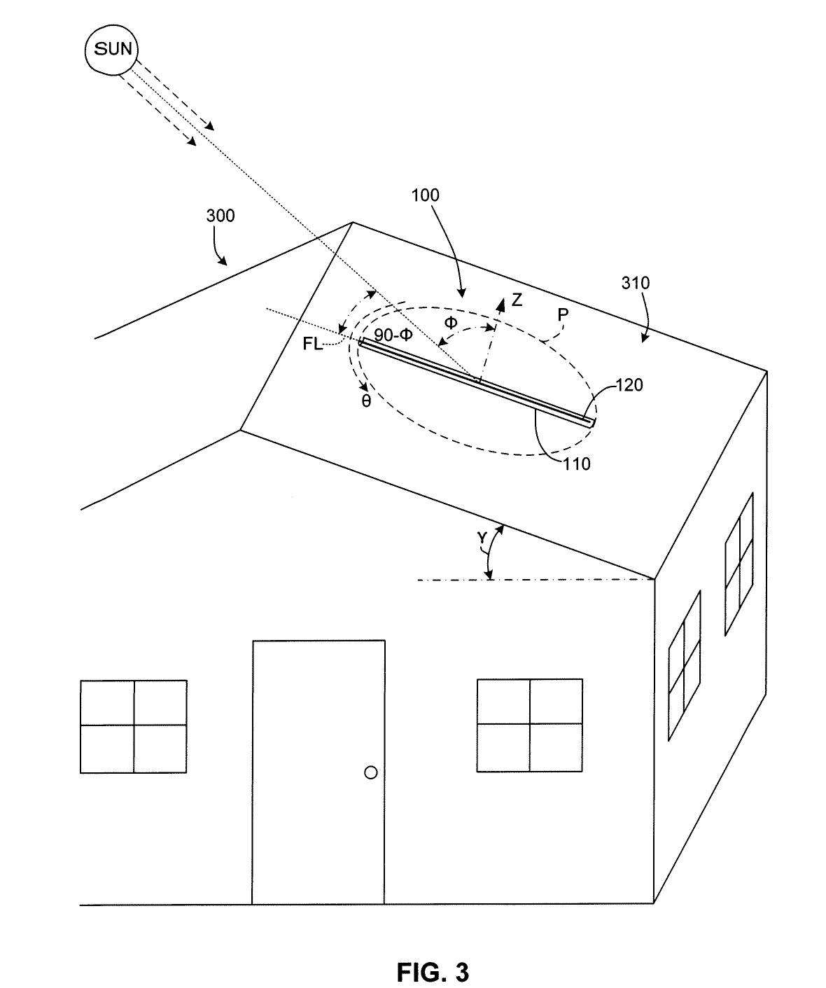

FIG. 3 is a perspective view depicting solar-electricity generation device 100 disposed on the planar rooftop (support surface) 310 of a residential house 300 having an arbitrary pitch angle γ. In this embodiment, device 100 is mounted with axis Z disposed substantially perpendicular planar rooftop 310 such that plane P defined by PV element 120 remains parallel to the plane defined by rooftop 310 as trough reflector 110 rotates around said axis Z. As depicted in this figure, a benefit of the present invention is that the substantially vertical rotational axis Z of device 100 allows tracking to take place in the plane of rooftop 310 of a residential house for most pitch angles γ. Further, because trough reflector 110 remains a fixed, short distance from rooftop 310, this arrangement minimizes the size and weight of the support structure needed to support and rotate device 100, thereby minimizing engineering demands on the foundation (i.e., avoiding significant retrofitting or other modification to rooftop 310).

Mathematically, as indicated in FIG. 3, for every position of the sun there exists one angle θ (and 180°+θ) around which reflector trough 110 rotates, such that the sun's ray will all focus onto PV element 120. FIG. 3 also illustrates that for any plane P there is a unique normal vector, and the incident angle of sunlight is measured off the normal as “Φ”, and the two lines subtend an angle which is simply 90°−Φ. The projection line always exists, and so, no matter where and how trough reflector 110 is mounted, as long PV element 120 rotates in plane P around the normal vector (i.e., axis Z), trough reflector 110 will eventually be positioned parallel to the projection line, and hence PV concentration will be carried out properly. The resulting high efficiency of device 100 means that, given a sufficient number and size of trough reflectors, etc., a typical rooftop 310 provides more than enough space to supply all electricity needed by house 300. Thus, for every dollar a home owner invests in a system including device 100, he or she saves five dollars in electricity bill. When scaled up to world population, no land is taken away, and only 0.3w of earth's dry surface covered to provide electricity for every home.

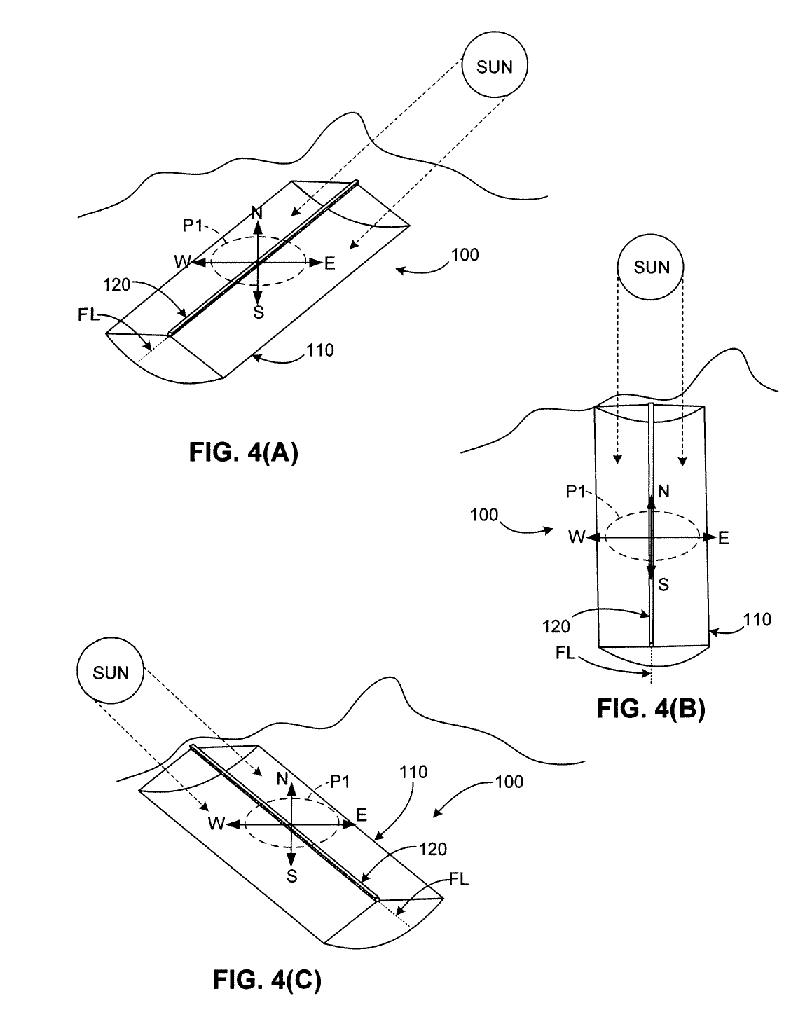

FIGS. 4(A) to 4(C) are simplified perspective diagrams depicting device 100 in operation during the course of a typical day in accordance with an embodiment of the present invention. In particular, FIGS. 4(A) to 4(C) illustrate the rotation of trough reflector 110 such that PV element 120 (and focal line FL) remain in plane P, and such that PV element 120 (and focal line FL) are aligned parallel to the incident sunlight. As indicated by the superimposed compass points, this rotation process includes aligning trough reflector 110 in a generally east-west direction during a sunrise time period (depicted in FIG. 4(A)), aligning trough reflector 110 in a generally north-south direction during a midday time period (depicted in FIG. 4(B)), and aligning trough reflector 110 in a generally east-west direction during a sunset time period (depicted in FIG. 4(C)). This process clearly differs from conventional commercial trough arrays that rotate around a horizontal axis and remain aligned in a generally north-south direction throughout the day. The inventors note that some conventional commercial trough arrays are aligned in a generally east-west direction (as opposed to north-south, as is customary), and adjust the tilt angle of their trough reflectors south to north to account for the changing positions of the sun between summer to winter, i.e., instead of pivoting 180 degrees east to west from morning to evening. However, unlike the architecture in this invention, these east-west aligned trough arrays do not rotate their troughs around perpendicular axes. Also, in many part of the world the sun moves along an arc in the sky. Thus, even though the angular correction is small, over the course of a day the east-west aligned troughs still have to pivot along their focal line to keep the focused sunlight from drifting off.

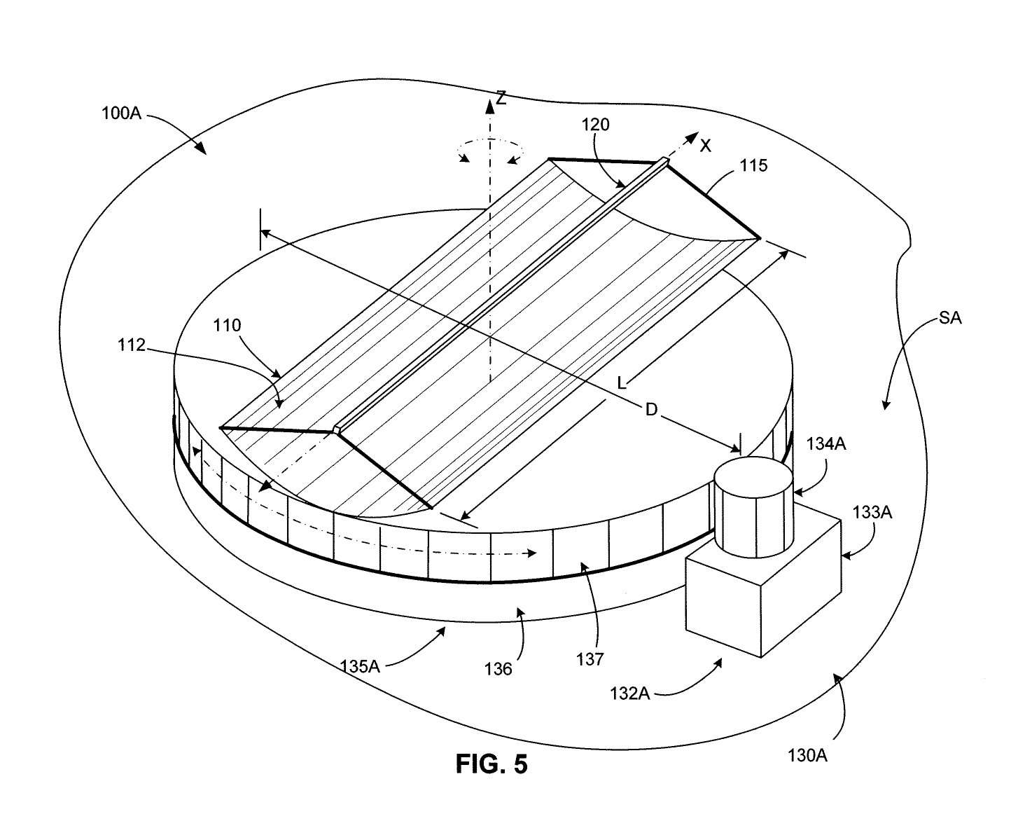

FIG. 5 is a perspective view showing a solar-electricity generation device (apparatus) 100A according to a specific embodiment of the present invention. Similar to the embodiments described above, device 100A generally includes a trough reflector 110, having a mirrored (reflective) surface 112 shaped to reflect solar (light) beams B onto a focal line FL, and a photoreceptor 120 mounted in fixed relation to trough reflector 110 along focal line FL. However, device 100A differs from the earlier embodiments in that it includes a tracking system 130A having a circular (e.g., disk-shaped) base structure 135A for rotatably supporting trough reflector 110, and a peripherally positioned drive system 132A for rotating trough reflector 110 relative to the underlying support surface SA.

According to an aspect of the disclosed embodiment, circular base structure 135A facilitates utilizing device 100A in residential settings by distributing the weight of trough reflector 110 over a larger area. In the disclosed embodiment, circular base structure 135A includes a fixed base 136A that is fixedly mounted onto support surface SA, and a movable support 137 that rotates on fixed base 136 by way of a track (not shown) such that trough reflector 110 rotates around vertical axis Z. Although shown as a solid disk, those skilled in the art will recognize that a hollow (annular) structure may be used to reduce weight, further facilitating the installation of device 100A onto a residential house without requiring modifications to the rooftop support structure.

In accordance with another aspect of the present embodiment, trough reflector 110 has a longitudinal length L measured parallel to focal line FL, and base structure 135A has a peripheral edge E defining a diameter D that is that is greater than or equal to longitudinal length L. By making the diameter of base structure 135A as wide as possible, the weight of device 100A may be distributed over a larger portion of underlying support surface SA, thereby reducing engineering requirements and further facilitating residential rooftop installation. This is further supported by the fact that any rotation affects all troughs on a circular structure equally, whereas through a long torsional linkage the trough sections away from the driving gear may not focus properly due to wind loading or gravity.

In accordance with yet another aspect of the present embodiment, peripherally positioned drive system 132A includes a motor 133A and a gear 134A (or other linking mechanism) that is coupled to a corresponding gear/structure disposed on peripheral edge E of movable support 137. This arrangement provides a solar parabolic trough reflector design that is small in size, uses only one motor 133A to rotate movable support (circular disc) 137 that may have a several meter-square surface area, and can be mounted on slanted residential roof because the rotation is kept within the plane of the roof.

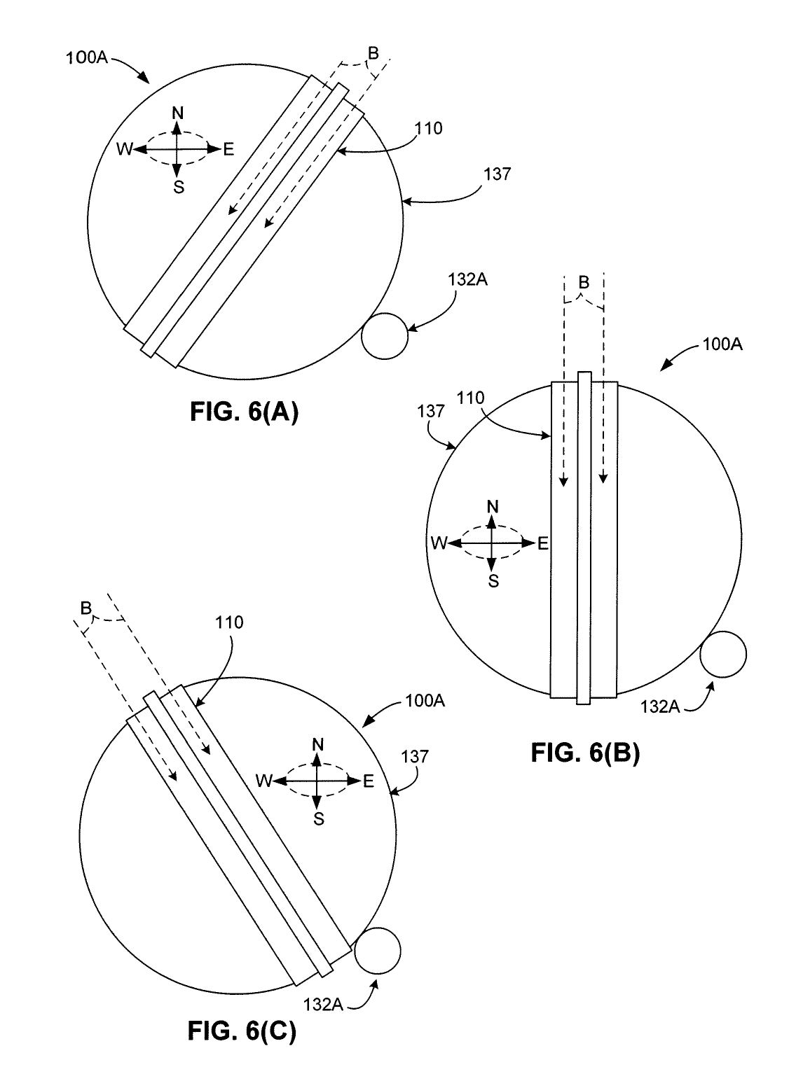

Referring to FIGS. 6(A) to 6(C), which show device 100A during operation, tracking system 130A also includes a sensor or feedback system (not shown) that detect a position of the sun relative to trough reflector 110, and cause drive system 132A (e.g., motor 133A and gear 134A; see FIG. 5) to apply torque to peripheral edge E of movable support 137 such that trough reflector 110 is rotated into a position in which the focal line FL is parallel to solar beams B generated by the sun in the manner described above. Because engineering requirements to withstand wind and gravity on a rotating platform is kept to a minimum, and because the motor is not required to rotate at high speeds, this arrangement minimizes the torque required by motor 133A that is needed to rotate trough reflector 110 around vertical axis Z, thereby reducing the cost of tracking system 130A. Moreover, this arrangement may be extended to turn several circular disks simultaneously using a single motor, further extending the efficiency of the overall system.

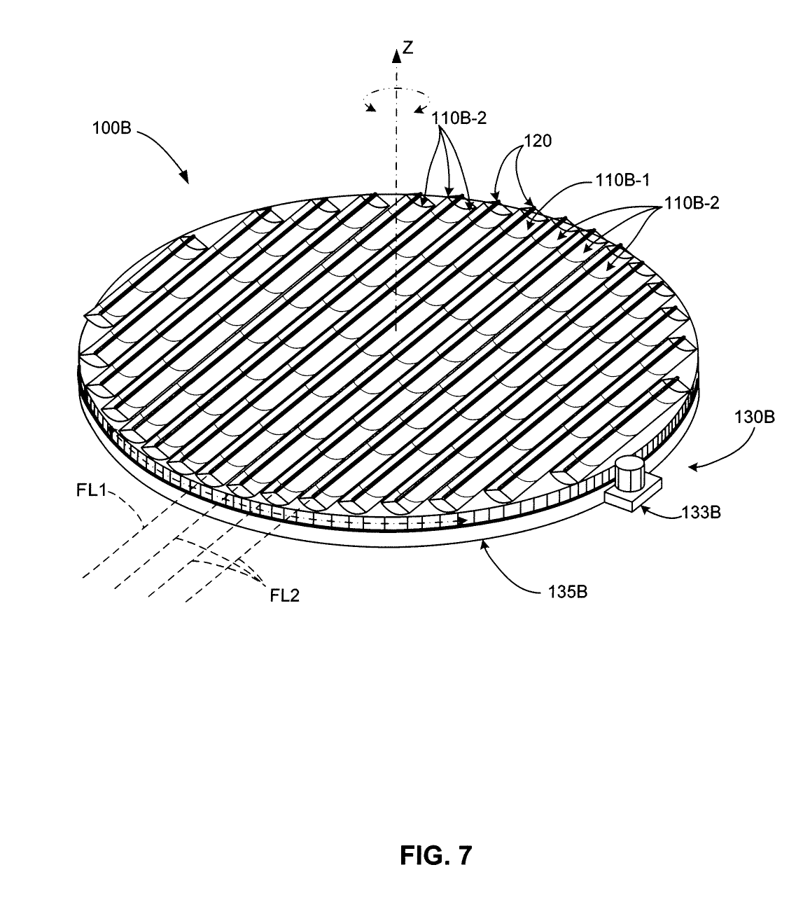

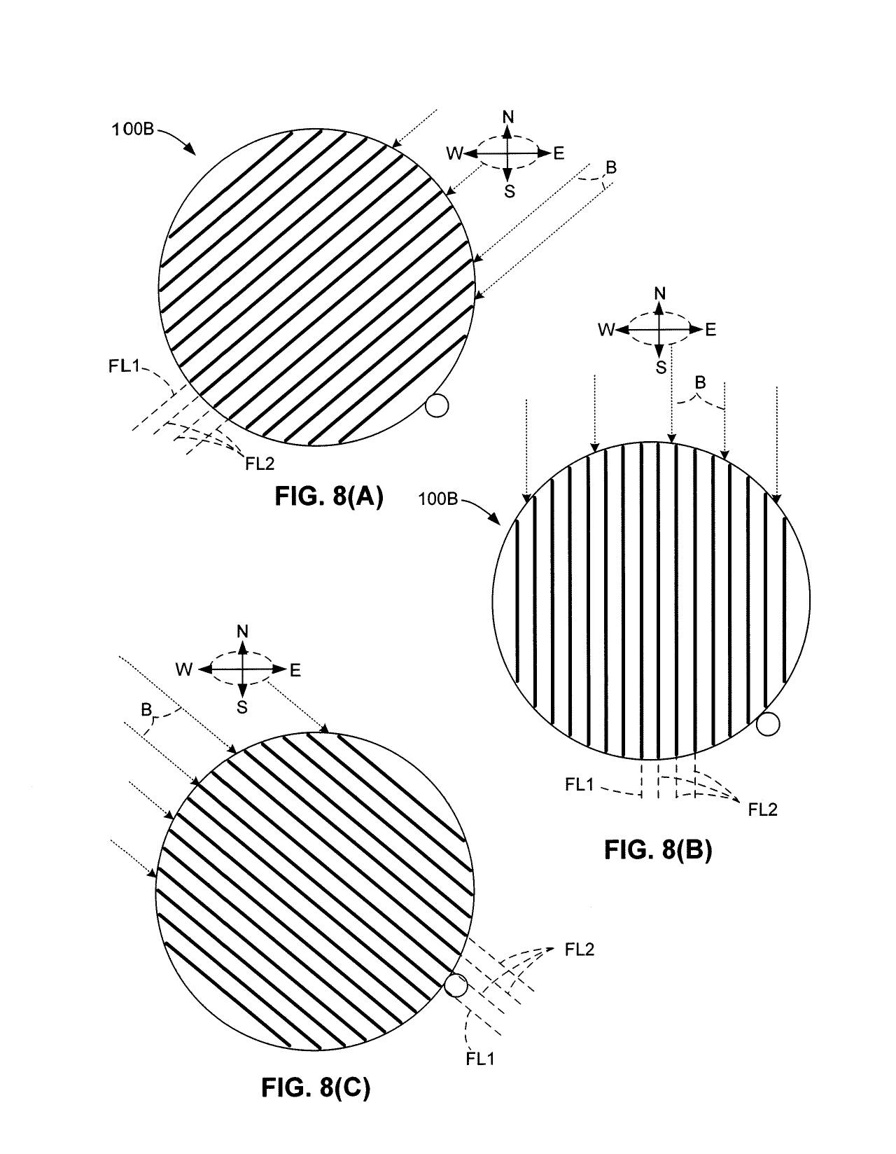

FIG. 7 is a top side perspective view showing a solar-electricity generation device 100B according to another specific embodiment of the present invention. Similar to device 100A (described above), device 100B utilizes a tracking system 130B having a circular base structure 135B and a peripherally positioned drive system 132B for rotating circular base structure 135B relative to an underlying support surface around an axis Z. However, device 100B differs from previous embodiments in that, in addition to a centrally-disposed trough reflector 110B-1 similar to that used in device 100A, device 100B includes one or more additional (second) trough reflectors 110B-2 that are fixedly coupled to circular base structure 135B, where the focal lines FL2 of each additional trough reflectors 110B-2 is parallel to the focal line FB1 of trough reflector 110B-1. According to this embodiment, the multiple trough reflectors 110B-1 and 110B-2 are rotated by a single small motor 133B mounted on the peripheral edge circular base structure 135B using very little power in comparison to that needed in conventional trough reflector arrangements. The weight of trough reflectors 110B-1 and 110B-2 is thus spread by circular base structure 135B over a large area, further facilitating rooftop mounting. The low profile and in-plane rotation of the trough reflectors reduces the chance of wind and storm damage in comparison to conventional trough reflector arrangements. Referring to FIGS. 8(A) to 8(C), device 100B is rotated in operation similar to the embodiments described above, but all focal lines FL1 and FL2 are aligned parallel to the projections of solar beams onto the rotating disc B.

In accordance with a residential embodiment of the invention, each trough reflector has a width of 4-inches and is a few feet long, depending on where they are mounted on a rotating disc which is in turn mounted onto a roof top, with circular base structure 135B being approximately six feet in diameter. The specific dimensions are chosen only to keep the overall thickness to be within a few inches above the rooftop. The dish rotates to focus sun's ray but the rotation stays in the plane of the substrate, and need not rise out of plane so mechanical requirement is much reduced than conventional solar arrays. By referring to the rooftop as substrate, the inventors wish to emphasize that devices produced in accordance with the present invention do not require a substantial foundation to withstand wind and storm; second, the concentrators need not take away inhabitable space; third, packing density is almost 1:1, just like ordinary rooftop solar panels.

Rough calculations for a device meeting the above specifications that a 8.8 KW system made with rotating trough arrays of the present invention can be set up on a rooftop and takes up only 59 meter². This system will supply 53 KWHr per day, and, at $0.1 per KWHr, will save the owner $1920 per year. The inventors currently estimate that the material cost of such a system to be approximately $5,000, with the component costs broken down into the following:
1. Silicon PV, at $0.20 per Watt, $1720
2. Converter box to and from 110VAC, $500
3. Motor and tracking System, $1000
4. Aluminum, 200 Kg, at $2.70 per Kg, $540
5. Stainless Steel or other reflective material, 75 Kg at $4 per lb, $662
6. Steel structures, 180 Kg at $1000 per ton, $180
7. Water sprinkler system surveillance electronics, $500.

Thus, the total $5120 for a system that lasts 25 years. Additionally, service for 25 years at $200 per year, $5000. Assuming the above numbers are realistic, the present invention provides a PV system that reclaims the required investment plus service in five years and three months. Lastly, the inventors note that the rotating trough array scheme of the present invention can be scaled up to the world population of 6 billion people, assuming that the previous calculation are for a family of four people and including electricity to charge two future electric vehicles. The land area needed to provide same for the world's population comes to only three square miles for every thousand sq. miles of land within the 45 degree North and South latitude. If the disc is implemented in a commercial solar-electric farm, size can be much enlarged to optimize for its specific requirements.

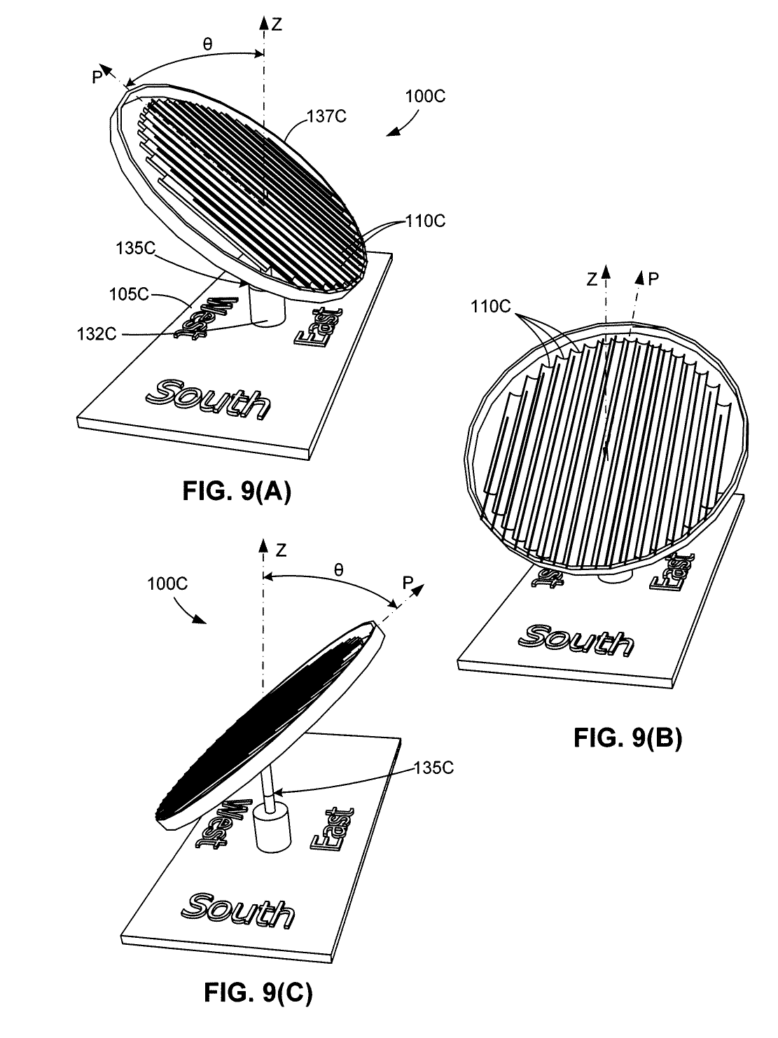

FIGS. 9(A), and 9(B) and 9(C) are simplified top side perspective views showing a solar-electricity generation device 100C according to another specific embodiment of the present invention. Similar to device 100B (described above), device 100C utilizes a tracking system having a circular support structure 137C that supports multiple trough reflectors 110C in a parallel arrangement, and a centrally positioned drive system 132C for rotating circular support structure 137C relative to an underlying support surface 105C around an axis Z defined by a support/drive shaft 135C. Device 100C differs from previous embodiments in that circular support structure 137C is disposed in a raised, angled position by support/drive shaft 135C such that the plane defined by disc-shaped support structure 137C defines an angle θ with reference to axis Z, whereby support structure 137C is turned by a motor (drive system 132C) such that trough reflectors 110C are collectively directed to face east, north and west throughout the day, as depicted in FIGS. 9(A), and 9(B) and 9(C). Note that trough reflectors 110C are aligned within circular support structure 137C such that the focal line of each trough reflector 110C is maintained at angle e as circular support structure 137C is rotated around axis Z. Although raising and tilting the plane defined by circular support structure 137C potentially increases wind effects over the perpendicular arrangement described above with reference to FIGS. 5-8, the raised arrangement utilized by solar-electricity generation device 100C may provide better solar light conversion that may be useful is some commercial applications.

Although the present invention has been described with respect to certain specific embodiments, it will be clear to those skilled in the art that the inventive features of the present invention are applicable to other embodiments as well, all of which are intended to fall within the scope of the present invention. For example, optical elements like prisms and wedges that use reflection and/or total internal reflection to concentrate light into a linear or rectangular area can also be used instead of a trough reflector. In this case the photovoltaic cells are positioned of the long ends of the concentrating optical element where the light is being concentrated. Further, off-axis conic or aspheric reflector shapes may also be used to form a trough-like reflector. In this case the photovoltaic cells will still be positioned off the aligned parallel to the trough but will be positioned and tilted around the long axis of the trough. Referring to FIG. 1, the rotational axis Z is perpendicular to the focal line FL. However, this invention can be used in a system where the rotational axis can be anywhere in the plane formed by the previous Z, and FL. In this general configuration, the trough will be rotated to an angular position where the incident solar beams run parallel to (but not necessarily in) this plane that is formed by the new and the previous Z, and also FL. This configuration is useful because large commercial trough arrays may be constructed to have the troughs inclined to compensate for latitude, and for ease of cleaning. Yet these trough arrays can be rotated on a horizontal platform which is not parallel to the plane formed by the multiple focal lines.

1. An apparatus for solar-electricity generation comprising:
a first trough reflector having a reflective surface defining a first focal line;
a first photovoltaic element disposed on the first focal line; and
means for rotating the first trough reflector around an axis, wherein the axis is non-parallel to the focal line.

2. The apparatus of claim 1, further comprising a support structure connected to the first trough reflector and to the first photoreceptor such that the first photoreceptor is maintained in a fixed position relative to the first trough reflector.

3. The apparatus of claim 2, wherein the support structure comprises one of a transparent support member and a plurality of support arms extending between the first trough reflector and the first photovoltaic element.

4. The apparatus of claim 1, wherein said axis is disposed substantially perpendicular to the first focal line such that the linear photoreceptor remains in a predetermined plane that is perpendicular to the axis when said first trough reflector rotates around said axis.

5. The apparatus of claim 1, wherein said means comprises a tracking system including means for detecting a position of the sun relative to trough reflector, and means for rotating the trough reflector such that the first focal line is parallel to solar beams generated by the sun that are directed onto the trough reflector.

6. The apparatus of claim 1, wherein said tracking system including means for controlling a rotational position of the trough reflector such that:
during a sunrise time period, the focal line is aligned in a first generally east-west direction,
during a midday time period, the focal line is aligned in a generally north-south direction, and
during a sunset time period, the focal line is aligned in a second generally east-west direction.

7. The apparatus of claim 1,
wherein the first trough reflector has a longitudinal length measured parallel to the focal line,
wherein said means comprises a circular base structure including means for rotating relative to an underlying support surface around said axis, and having a peripheral edge defining a diameter that is greater than or equal to the longitudinal length of said first trough reflector, and
wherein the first trough reflector is fixedly mounted on the circular base structure such that rotation of the circular base structure relative to said underlying support surface produces rotation of the first trough reflector around said axis.

8. The apparatus of claim 7, wherein said means comprises a tracking system including:
a drive system coupled to the peripheral edge of the circular base structure,
means for detecting a position of the sun relative to trough reflector, and
means for causing the drive system to apply torque to the peripheral edge of the circular base structure such that the trough reflector is rotated into a position in which the first focal line is parallel to solar beams generated by the sun that are directed onto the trough reflector.

9. The apparatus of claim 7, further comprising one or more second trough reflectors fixedly coupled to said circular base structure, each of said one or more second trough reflectors including an associated focal line, wherein the associated focal lines of the one or more second trough reflectors are parallel to the focal line of the first trough reflector.

10. The apparatus of claim 1, further comprising one or more second trough reflectors fixedly coupled to said first trough reflector, each of said one or more second trough reflectors including an associated focal line, wherein the associated focal lines of the one or more second trough reflectors are parallel to the first focal line of the first trough reflector.

11. The apparatus of claim 10, wherein said one or more second trough reflectors and said first trough reflector are disposed in a raised and tilted position such that a plane defined by said one or more second trough reflectors and said first trough reflector defines an angle with reference to said axis.

12. A method for generating solar-electricity using a first trough reflector, wherein the first trough reflector defines a first focal line, the method comprising:
disposing the first trough reflector on a planar support surface such that the first focal line defines an angle relative to the planar support surface; and
rotating the first trough reflector around an axis that is substantially perpendicular to the planar support surface, whereby the first focal line remains disposed at said angle relative to said planar surface while said first trough reflector rotates around said axis.

13. The method of claim 12, further comprising fixedly mounting a first photovoltaic element to the first trough reflector such that the first photovoltaic element is disposed along the first focal line, whereby rotation of the first trough reflector causes said first photovoltaic element to rotate around the axis while remaining within the plane.

14. The method of claim 12, further comprising:
detecting a position of the sun relative to trough reflector, and
rotating the trough reflector such that the first focal line is parallel to solar beams generated by the sun that are directed onto the trough reflector.

15. The method of claim 14, wherein said rotating the trough reflector comprises:
during a sunrise time period, aligning the focal line in a first generally east-west direction,
during a midday time period, aligning the focal line in a generally north-south direction, and
during a sunset time period, aligning the focal line in a second generally east-west direction.

16. The method of claim 12, wherein disposing the first trough reflector on the planar support surface comprises disposing the first trough reflector on a roof of a residential house.

17. The method of claim 12, wherein disposing the first trough reflector on the planar support surface comprises disposing the first trough reflector on a circular base structure mounted on the planar support surface, wherein the circular base structure includes a peripheral edge defining a diameter that is greater than or equal to a longitudinal length of said first trough reflector, and
wherein rotating the first trough reflector comprises applying a force to the peripheral edge of the circular base structure such that the circular base structure rotates relative to the planar support surface around said axis.

18. The method of claim 17, further comprising fixedly connecting one or more second trough reflectors to said circular base structure, each of said one or more second trough reflectors including an associated focal line, wherein the associated focal lines of the one or more second trough reflectors are parallel to the focal line of the first trough reflector.

19. The method of claim 2, further comprising fixedly connecting one or more second trough reflectors to said first trough reflector, each of said one or more second trough reflectors including an associated focal line, wherein the associated focal lines of the one or more second trough reflectors are parallel to the focal line of the first trough reflector such that rotating the first trough reflector around the axis causes said associated focal lines to remain disposed within the plane.

20. A method for generating solar-electricity using a trough reflector, wherein the trough reflector defines a focal line, the method comprising:
mounting the trough reflector onto a planar support surface such that the focal line defines a predetermined angle relative to the support surface, and
rotating the trough reflector around an axis that is substantially perpendicular to the support surface such that:
during a sunrise time period, the focal line is aligned in a first generally east-west direction,
during a midday time period, the focal line is aligned in a generally north-south direction, and
during a sunset time period, the is aligned in a second generally east-west direction.

21. The method of claim 20, wherein mounting the trough reflector comprises mounting the trough reflector on a rooftop surface of a residential house.
